(19) United States
(12) Patent Application Publication
(10) Pub. No.: US 2026/0241825 A1
(43) Pub. Date: Aug. 20, 2026

(54) CHARGER AND MOTOR VEHICLE

(71) Applicant: MAHLE International GmbH, Stuttgart (DE)

(72) Inventors: Torbjorn Hallberg, Valencia (ES); Francisco Gonzalez Espin, La Pobla de Valbona (ES); Alberto Garcia Briz, Valencia (ES)

(21) Appl. No.: 19/543,823

(22) Filed: Feb. 18, 2026

(30) Foreign Application Priority Data
Feb. 19, 2025 (DE) 102025106294.3

(51) Int. Cl. B60L 53/62; B60L 53/18; B60L 53/302; H01F 27/28; H01F 38/14; H02J 50/00; H02J 50/10

(52) U.S. Cl. CPC B60L 53/62; B60L 53/18; B60L 53/302; H01F 27/2876; H01F 38/14; H02J 50/005; H02J 50/10

(57) ABSTRACT

A charger, may be configured as an on-board charger for cable-based charging and for wireless charging of a traction battery of a motor vehicle. The charger may include a housing, a power circuit, an induction coil, and a cooling circuit for conveying a coolant and for cooling the power electronics and the induction coil. The charger may further include a cable connection for electrically connecting the charger to a charging socket of the motor vehicle configured for cable-based charging. Further, the charger may include a battery connection for electrical connection to the traction battery, a control connection for electrical connection to a control unit for controlling a charging process, a coolant inlet connection for supplying the coolant to the cooling circuit, and a coolant outlet connection for discharging the coolant from the cooling circuit.

### CROSS-REFERENCE TO RELATED APPLICATION

This application claims priority to German Patent Application No. DE 10 2025 106 294.3, filed on Feb. 19, 2025, the contents of which is hereby incorporated by reference in its entirety.

### TECHNICAL FIELD

The present invention relates to a charger for a battery-electric motor vehicle as well as a motor vehicle equipped with such a charger.

### BACKGROUND

A battery-electric motor vehicle has an electrical traction battery, which may be charged by means of an external electrical energy source. For charging the traction battery, the motor vehicle is equipped with a charger, which supplies the electrical energy fed via the external energy source to the traction battery for charging. In this process, alternating current supplied to the charger is converted into direct current, which may then be supplied to the traction battery for charging.

For electrical connection to the respective external energy source, the motor vehicle is typically equipped with a charging socket, which is electrically connected within the vehicle to the charger and via which cable-based charging may be carried out. For this purpose, a charging cable connected to the external energy source is plugged into the charging socket. Furthermore, induction charging systems for wireless charging of the traction battery are known, in which the external energy source is electrically connected to a stationary induction charging device, which, for example, may be arranged and fixed on a ground surface in a region of a parking space of the motor vehicle. The induction charging system is additionally equipped with a mobile induction charging device, which is arranged on the motor vehicle in a region of a vehicle floor and which is electrically connected to a charger. The vehicle may now be positioned on the parking space such that electrical energy may be transmitted by induction from the stationary induction charging device to the mobile induction charging device, which is then supplied to the charger. The stationary induction charging device has an induction coil, which may be referred to as a transmitting coil. The mobile induction charging device also has an induction coil, which may be referred to as a receiving coil.

If the motor vehicle is configured both for cable-based charging and for wireless charging, separate chargers are typically used for this purpose, namely a charger for cable-based charging and a charger for wireless charging. In this case, the two separate chargers are separately electrically connected to the traction battery and separately electrically connected to a control unit for controlling a charging process. Furthermore, the separate chargers may each be equipped with a cooling circuit, which may both be integrated into a cooling device of the vehicle. Since the respective charger is connected and fixed to the respective vehicle during proper use, it may also be referred to as an on-board charger.

The present invention addresses the problem of specifying an improved or at least an alternative embodiment for a charger of the type described above, as well as for a motor vehicle equipped therewith, which is distinguished, in particular, in that it requires little installation space and may be implemented in a comparatively cost-effective manner.

This problem is solved according to the invention by the subject matter of the independent claim(s). Advantageous embodiments are the subject matter of the dependent claims.

### SUMMARY

The present invention is based on the general concept of combining a charger that is configured for cable-based charging and a charger that is configured for wireless charging with one another in such a manner that a common housing may be used for this purpose, wherein components that serve the same purpose in the two different chargers are combined in the combined charger. By integrating the two chargers into a common housing, the combined charger according to the invention requires less installation space than two separate chargers. By the shared use of components of the combined charger, fewer components are required than in the case of two separate chargers, whereby manufacturing costs may additionally be reduced.

In other words, the invention proposes a charger for a battery-electric motor vehicle, which is configured as an on-board charger for cable-based charging and for wireless charging of a traction battery of the motor vehicle. For this purpose, the charger comprises a housing, power electronics arranged inside the housing, an induction coil mounted on or in the housing and electrically connected to the power electronics, a cooling circuit arranged on or in the housing for conveying a coolant and for cooling the power electronics and the induction coil, a cable connection arranged on the outside of the housing and electrically connected to the power electronics for electrically connecting the charger to a charging socket of the motor vehicle configured for cable-based charging, a battery connection arranged on the outside of the housing and electrically connected to the power electronics for electrically connecting to the traction battery, a control connection arranged on the outside of the housing and electrically connected to the power electronics for electrically connecting to a control unit of the motor vehicle for controlling a charging process, a coolant inlet connection arranged on the outside of the housing and fluidically connected to the cooling circuit for supplying the coolant to the cooling circuit, and a coolant outlet connection arranged on the outside of the housing and fluidically connected to the cooling circuit for discharging the coolant from the cooling circuit.

Thus, the charger presented here has a battery connection, which may be used both during cable-based charging and during wireless charging for supplying the electrical energy to the traction battery. Furthermore, the charger presented here has a control connection, which may be used both during cable-based charging and during wireless charging for controlling the respective charging process. Furthermore, a common cooling circuit is provided, which may be used both during cable-based charging and during wireless charging for cooling the power electronics and, optionally, the induction coil.

In the present context, a “configuration” is synonymous with a “design” and/or an “arrangement” and/or a “programming,” such that the formulation “configured such that” is synonymous with the formulation “designed and/or arranged and/or programmed such that.”

The cable connection may be designed for high voltage and for high power and, for this purpose, may be configured, in particular, as a three-phase connection.

The induction coil may be arranged inside the housing or on the outside of the housing.

According to an advantageous embodiment, the charger may have an on-board electrical system connection arranged on the outside of the housing and electrically connected to the power electronics for electrically connecting to an on-board electrical system of the motor vehicle. Via the on-board electrical system connection, the on-board electrical system of the motor vehicle may be supplied with electrical energy, for example, during the charging process, electrical components of the motor vehicle that are electrically connected to the on-board electrical system may be supplied with electrical energy, such as the control unit. Likewise, in this manner, during the charging process, a conventional on-board electrical system battery may be charged.

According to another embodiment, it may be provided that the charger has a cooling plate arranged on or in the housing, in which the cooling circuit is formed. Such a cooling plate may be configured to be flat and planar, such that it requires little installation space and may dissipate a large amount of heat. A cooling circuit having such a cooling plate is distinguished by a high efficiency. According to an advantageous embodiment, the cooling plate may be arranged inside the housing. In another embodiment, the cooling plate may form a cover or a lid for the housing.

Expediently, the cooling plate may be arranged geometrically between the power electronics and the induction coil. Thus, the cooling plate may, on the one hand, absorb heat from the power electronics and, on the other hand, absorb heat from the induction coil separately, which improves cooling.

According to an advantageous embodiment, it may be provided that, on an upper side of the cooling plate facing the power electronics, at least one wall projects, which is connected to the cooling plate in a heat-transferring manner and which delimits a receiving region that is open at an end facing away from the cooling plate and is configured to receive at least one component of the power electronics. The respective component of the power electronics arranged in such a receiving region may be cooled particularly efficiently, since heat may also be dissipated from the respective component via the wall. In particular, the respective component may, in this case, be connected to the respective wall in a heat-transferring manner. Appropriately, a plurality of such receiving regions may be formed on the upper side of the cooling plate, in each of which at least one component of the power electronics is arranged. The respective component of the power electronics may in this case extend into the receiving region through the open end of the respective receiving region.

According to an advantageous embodiment, the cooling plate may have at least one plate opening, through which at least one connection element of the induction coil is guided, which is configured for electrically connecting the induction coil to the power electronics. As a result, a particularly compact structural configuration for the charger may be achieved.

According to an advantageous embodiment, it may be provided that the charger has a ferrite plate arrangement arranged on or in the housing, which is arranged geometrically between the induction coil and the cooling circuit. The ferrite plate arrangement has a plurality of ferrite plates, which are each magnetically conductive and configured such that the efficiency of inductive energy transfer via the induction coil may be significantly improved. Expediently, the induction coil may be thermally conductively connected to the ferrite plate arrangement, such that the ferrite plates may absorb and dissipate heat from the induction coil.

According to a particularly advantageous embodiment, the ferrite plate arrangement may be thermally conductively connected to the cooling plate. Thus, heat generated in the induction coil during wireless charging may be transferred to the ferrite plates and from the ferrite plates to the cooling plate.

According to an advantageous embodiment, the ferrite plate arrangement may have at least one arrangement opening, through which at least one connection element of the induction coil is guided, which is configured for electrically connecting the induction coil to the power electronics. By this measure, a particularly compact structural configuration of the charger is obtained.

A battery-electric motor vehicle according to the invention comprises a traction battery, a cooling device for cooling and conveying a coolant, a charging socket for cable-based charging of the traction battery, a control unit for controlling a charging process, and a charger of the type described above. In the vehicle, the coolant inlet connection and the coolant outlet connection are fluidically connected to the cooling device. Furthermore, the cable connection is electrically connected to the charging socket, the battery connection is electrically connected to the traction battery, and the control connection is electrically connected to the control unit.

Further important features and advantages of the invention result from the dependent claims, from the drawings, and from the associated description of the figures with reference to the drawings.

It is understood that the features mentioned above and the features still to be explained below are not only usable in the respectively indicated combination, but also in other combinations or individually, without departing from the scope of the invention as defined by the claims. Components of a superordinate unit mentioned above and components still to be mentioned below, such as of a device, an apparatus, or an arrangement, which are designated separately, may form separate structural parts or components of this unit or may be integral regions or sections of this unit, even if this is illustrated differently in the drawings.

Preferred exemplary embodiments of the invention are illustrated in the drawings and are explained in greater detail in the following description, wherein identical reference signs refer to identical or similar or functionally identical components.

### BRIEF DESCRIPTION OF THE DRAWINGS

It shows, in each case schematically,

FIG. 1 shows an isometric view of a charger,

FIG. 2 shows an isometric view of the charger in an expanded view,

FIG. 3 shows a highly simplified, circuit-diagram-like schematic representation of a battery-electric motor vehicle.

### DETAILED DESCRIPTION

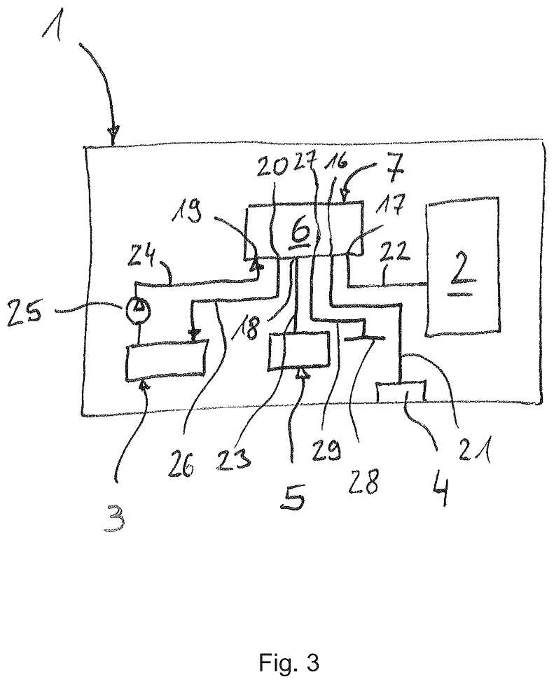

Corresponding to FIG. 3, a battery-electric motor vehicle 1 symbolically illustrated by a frame comprises a traction battery 2, a cooling device 3 for cooling and conveying a coolant, a charging socket 4 for cable-based charging of the traction battery 2, a control unit 5 for controlling a charging process, and a charger 6. The charger 6 is configured as an on-board charger 7 and is accordingly fixedly arranged on the vehicle 1. The charger 6 is further configured for cable-based charging and for wireless charging of the traction battery 2 of the vehicle 1.

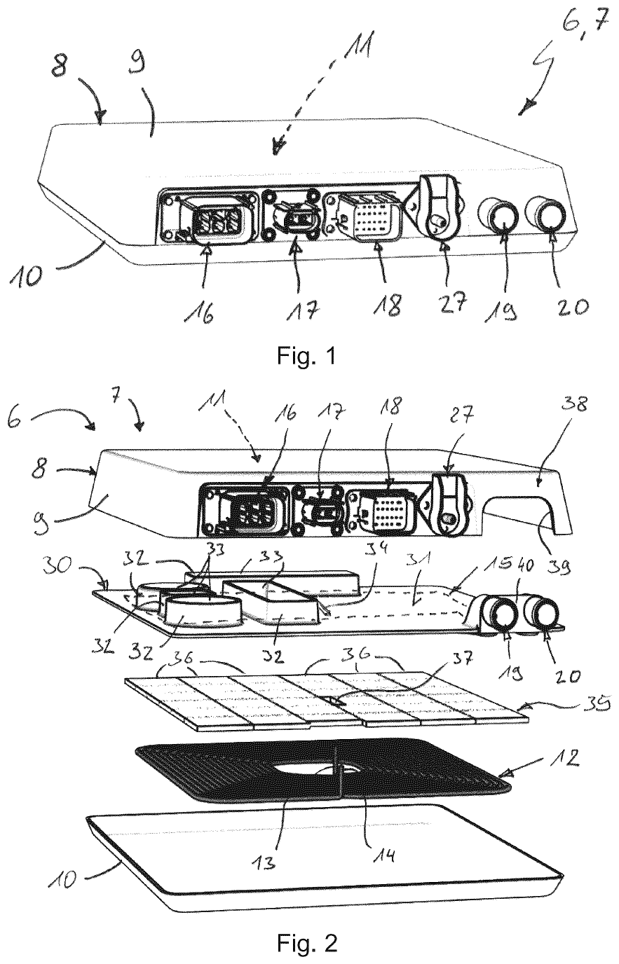

Corresponding to FIGS. 1 and 2, the charger 6, which is configured as an on-board charger 7, comprises a housing 8, which may expediently have a housing upper part 9 and a housing lower part 10, which may be configured in a shell-like manner and which may be fastened to one another for closing the housing 8. The housing lower part 10 is manufactured from a material that does not shield an electromagnetic field, for example, from a plastic. The charger 6 furthermore has power electronics 11, which are concealed here by the housing 8 and are arranged inside the housing 8.

According to FIG. 2, the charger 6 furthermore has an induction coil 12, which is arranged or mounted on or in the housing 8. In the illustrated exemplary embodiment, the induction coil 12 is arranged inside the housing lower part 10. The housing lower part 10 is configured for protecting the induction coil 12. The induction coil 12 is electrically connected to the power electronics 11. For this purpose, the induction coil 1 may have two connection elements 13, 14, which are configured in a purely exemplary manner as rod-shaped in FIG. 2 and which are provided for electrical connection to the power electronics 11. In the illustrated embodiment, the housing lower part 10 forms a lid or a cover for the housing upper part 9, such that, in the assembled state of FIG. 1, the housing upper part 9 is closed by the housing lower part 10 when the housing lower part 10 is fastened to the housing upper part 9 in order to form the housing 8. In this case, the induction coil 12 is arranged inside the housing 8.

According to FIG. 2, the charger 6 furthermore has a cooling circuit 15, which is indicated in simplified form in FIG. 2 by a broken line. The cooling circuit 15 is arranged inside the housing 8 and is configured for conveying a coolant and for cooling the power electronics 11 and the induction coil 12.

Corresponding to FIGS. 1 and 2, the charger 6 furthermore has, on the outside of the housing 8, a cable connection 16, a battery connection 17, a control connection 18, a coolant inlet connection 19, and a coolant outlet connection 20. The cable connection 16 is electrically connected to the power electronics 11 and in turn serves for electrically connecting the charger 6 to the charging socket 4 for cable-based charging of the traction battery 2. For this purpose, the cable connection 16 may be configured as a three-phase connection. In FIG. 3, the cable connection 16 is electrically connected to the charging socket 4 by a corresponding connecting line 21. The battery connection 17 is electrically connected to the power electronics 11 and serves to electrically connecting to the traction battery 2. In FIG. 3, the battery connection 10 is electrically connected to the traction battery 2 via a connecting line 22. The control connection 18 is electrically connected to the power electronics 11 and serves to electrically connect to the control unit 5. In FIG. 3, the control connection 18 is electrically connected to the control unit 5 via a control line 23. The coolant inlet connection 19 serves to supply the coolant to the cooling circuit 15 and is, for this purpose, fluidically connected to the cooling circuit 15. In FIG. 3, the cooling device 3 is fluidically connected to the coolant inlet connection 19 via a supply line 24. Expediently, the cooling device 3 may have a conveying device 25 for driving the coolant, in particular, a pump, which may expediently be arranged in the supply line 24. The coolant outlet connection 20 is fluidically connected to the cooling circuit 15 and serves to discharge the coolant from the cooling circuit 15. According to FIG. 3, the cooling device 3 is fluidically connected to the coolant outlet connection 20 via a return line 26.

According to FIGS. 1 and 2, the charger 6 may furthermore have an on-board electrical system connection 27 arranged on the outside of the housing 8, which is electrically connected to the power electronics 11 and which is configured for electrically connecting to an electrical on-board electrical system 28, which is illustrated symbolically in FIG. 3 as a line-shaped conductor section. According to FIG. 3, the on-board electrical system connection 27 may be electrically connected to the on-board electrical system 28 via a connecting line 29.

According to FIG. 2, the charger 6 may comprise a cooling plate 30, which here is configured to be flat and planar. The cooling plate 30 is arranged inside the housing 8 and/or between the housing upper part 9 and the housing lower part 10. In this cooling plate 30, the cooling circuit 15 is formed. For this purpose, the cooling plate 30 comprises a channel system, not shown here, which forms the cooling circuit 15. The cooling plate 30 is geometrically arranged between the power electronics 11 and the induction coil 12 in the housing 8. In this case, the induction coil 12 is configured to be flat and planar and extends parallel to the planar cooling plate 30. In another embodiment, not shown, the cooling plate 30 may form a lid or a cover for the housing upper part 9, such that the housing upper part 9, in the assembled state of FIG. 1, is closed by the cooling plate 30 when the cooling plate 30 is fastened to the housing upper part 9 in order to form the housing 8. In this case, the induction coil 12 is arranged on the outside of the housing 8.

In the example of FIG. 2, the cooling plate 30 comprises, on its upper side 31 facing the power electronics 11, a plurality of walls 32, which in each case project from the upper side 31 of the cooling plate 30, specifically in a direction toward the power electronics 11. The walls 32 are connected to the cooling plate 30 in a heat-transferring manner and in each case delimit a receiving region 33. The receiving regions 33 are, in this case, dimensioned and positioned such that they are configured and/or arranged to be complementary to components of the power electronics 11 that are not shown. The receiving regions 33 are configured to be open at an end facing away from the cooling plate 30 and are configured to receive at least one component of the power electronics 11. In other words, the receiving regions 33 are open upward, such that, in the assembled state, the respective components of the power electronics 11 dip into these receiving regions 33 from above.

Expediently, the coolant inlet connection 19 and the coolant outlet connection 20 may be fixedly connected to the cooling plate 20 [sic: 30] and may be fluidically connected to the cooling circuit 15 formed therein. According to FIG. 2, the cooling plate 30 may comprise at least one plate opening 34, which is positioned and dimensioned such that, in the assembled state of the charger 6, at least one of the connection elements 13, 14 of the induction coil 12 is guided through the respective plate opening 34 in the assembled state.

According to FIG. 2, the charger 6 may furthermore comprise a ferrite plate arrangement 35, which is arranged and/or fastened on or in the housing 8 and is, in this case, geometrically arranged between the induction coil 12 and the cooling circuit 15 and/or the cooling plate 30. The ferrite plate arrangement 35 is, in this case, configured to be planar and flat and extends parallel to the planar cooling plate 30. Expediently, the induction coil 12 is thermally conductively connected to the ferrite plate arrangement 35. Expediently, the ferrite plate arrangement 35 is, in turn, thermally conductively connected to the cooling plate 30. The ferrite plate arrangement 35 comprises a plurality of separate ferrite plates 36, which are arranged next to one another and which may each be configured to be flat and planar. The ferrite plate arrangement 35 may furthermore comprise at least one arrangement opening 37, which is arranged and dimensioned such that, in the assembled state of the charger 6, at least one of the connection elements 13, 14 of the induction coil 12 is guided through this arrangement opening 37.

In the preferred embodiment illustrated in FIGS. 1 and 2, the ferrite plate arrangement 35 is arranged inside the housing lower part 10 and, correspondingly, inside the housing 8.

In the embodiment shown in FIG. 2, it is furthermore provided that the housing upper part 9 comprises, in a cooling circuit connection region 38, a recess 39 that is open toward the housing lower part 10 and whose free internal cross section is larger than the sum of the external cross sections of the coolant inlet connection 19 and the coolant outlet connection 20. Furthermore, according to FIG. 2, a closure element 40 is arranged on the cooling plate 30, which is formed to be complementary to the recess 39. The coolant inlet connection 19 and the coolant outlet connection 20 are fluidically connected to the cooling circuit 15 through this closure element 40. In the assembled state, the closure element 40 closes the recess 39, wherein the closure element 40 bears directly against the housing upper part 9 upward and directly against the housing lower part 10 downward and is thus, in particular, sealingly connected.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase “at least one of” followed by successive elements separate by the word “and” (e.g., “at least one of A and B”) is to be interpreted the same as “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

1. A charger for a battery-electric motor vehicle, comprising:
a housing;
a power circuit arranged inside the housing;
an induction coil arranged on or in the housing and electrically connected to the power circuit;
a cooling circuit arranged inside the housing for conveying a coolant and for cooling the power circuit and the induction coil;
a cable connection externally arranged on the housing, electrically connected to the power circuit, for electrically connecting the charger to a charging socket of the battery-electric motor vehicle configured for cable-based charging;
a battery connection arranged on an outside of the housing and electrically connected to the power circuit for electrical connection to a traction battery of the battery-electric motor vehicle;
a control connection externally arranged on the housing, electrically connected to the power circuit, for electrical connection to a control unit for controlling a charging process;
a coolant inlet connection externally arranged on the housing, fluidically connected to the cooling circuit, for supplying the coolant to the cooling circuit; and
a coolant outlet connection externally arranged on the housing, fluidically connected to the cooling circuit, for discharging the coolant from the cooling circuit;
wherein the charger is configured as an on-board charger for cable-based charging and for wireless charging of the traction battery.

2. The charger according to claim 1, wherein the charger has an on-board electrical system connection arranged on the outside of the housing and electrically connected to the power circuit for electrically connecting to an electrical on-board electrical system of the battery-electric motor vehicle.

3. The charger according to claim 1, wherein the charger has a cooling plate arranged on or in the housing, in which the cooling circuit is formed.

4. The charger according to claim 3, wherein the cooling plate is geometrically arranged between the power circuit and the induction coil in the housing.

5. The charger according to claim 3, wherein on an upper side of the cooling plate facing the power circuit, at least one wall projects, which is connected to the cooling plate in a heat-transferring manner and delimits a receiving region that is open at an end facing away from the cooling plate and is configured to receive at least one component of the power circuit.

6. The charger according to claim 3, wherein the cooling plate comprises at least one plate opening, through which at least one connection element of the induction coil is guided for electrically connecting the induction coil to the power circuit.

7. The charger according to claim 1, wherein the charger comprises a ferrite plate arrangement arranged on or in the housing, which is geometrically arranged between the induction coil and the cooling circuit.

8. The charger according to claim 7, wherein the charger has a cooling plate arranged on or in the housing, in which the cooling circuit is formed; the induction coil is thermally conductively connected to the ferrite plate arrangement; and the ferrite plate arrangement is thermally conductively connected to the cooling plate.

9. The charger according to claim 7, wherein the ferrite plate arrangement has at least one arrangement opening through which at least one connection element of the induction coil for electrically connecting the induction coil to the power circuit is passed.

10. A battery-electric motor vehicle, comprising
a traction battery;
a cooling device including a cooling circuit for cooling and conveying a coolant;
a charging socket for cable-based charging of the traction battery;
a control unit for controlling a charging process; and
a charger, further comprising:
a housing;
a power circuit arranged inside the housing;
an induction coil arranged on or in the housing electrically connected to the power circuit;
a cable connection externally arranged on the housing for electrically connecting the charger to a charging socket of the battery-electric motor vehicle configured for cable-based charging;
a battery connection arranged an outside of the housing for electrically connecting the power circuit to the traction battery; and
a control connection externally arranged on the housing for electrical connection to the control unit for controlling a charging process;
wherein a coolant inlet connection and a coolant outlet connection are arranged on the housing and are fluidically connected to the cooling device; the cable connection is electrically connected to the charging socket; the battery connection is electrically connected to the traction battery; and the control connection is electrically connected to the control unit.

11. The battery-electric motor vehicle of claim 10, wherein the charger has an on-board electrical system connection arranged on the outside of the housing.

12. The battery-electric motor vehicle of claim 11, wherein the on-board electrical system is electrically connected to the power circuit for electrically connecting to an electrical on-board electrical system of the battery-electric motor vehicle.

13. The battery-electric motor vehicle of claim 10, wherein the charger has a cooling plate arranged on or in the housing in which the cooling circuit is formed.

14. The battery-electric motor vehicle of claim 13, wherein the cooling plate is geometrically arranged between the power circuit and the induction coil in the housing.

15. The battery-electric motor vehicle of claim 14, wherein on an upper side of the cooling plate facing the power circuit, at least one wall projects, which is connected to the cooling plate in a heat-transferring manner and delimits a receiving region that is open and at an end facing away from the cooling plate and is configured to receive at least one component of the power circuit.

16. The battery-electric motor vehicle of claim 15, wherein the cooling plate further comprises at least one plate opening, through which at least one connection element of the induction coil is guided for electrically connecting the induction coil to the power circuit.

17. The battery-electric motor vehicle of claim 10, wherein the charger comprises a ferrite plate arrangement arranged on or in the housing.

18. The battery-electric motor vehicle of claim 17, wherein the ferrite plate arrangement is geometrically arranged between the induction coil and the cooling circuit.

19. The battery-electric motor vehicle of claim 18, wherein the induction coil is thermally conductively connected to the ferrite plate arrangement.

20. The battery-electric motor vehicle of claim 19, wherein the ferrite plate arrangement includes at least one opening through which at least one connection element of the induction coil for electrically connecting the induction coil to the power circuit is passed.
